(19) United States
(12) Patent Application Publication
(10) Pub. No.: US 2026/0231545 A1
(43) Pub. Date: Aug. 6, 2026

(54) IMAGE SENSOR PACKAGE

(71) Applicant: SAMSUNG ELECTRONICS CO., LTD., Suwon-si (KR)

(72) Inventor: Du Sik JUNG, Suwon-si (KR)

(73) Assignee: SAMSUNG ELECTRONICS CO., LTD., Suwon-si (KR)

(21) Appl. No.: 19/343,979

(22) Filed: Sep. 29, 2025

(30) Foreign Application Priority Data
Feb. 5, 2025 (KR) 10-2025-0014331

(51) Int. Cl. H10F 39/00; H10F 39/95

(52) U.S. Cl. CPC H10F 39/804; H10F 39/811; H10F 39/95

(57) ABSTRACT

An image sensor package including: a package substrate, a first image sensor chip on the package substrate, a second image sensor chip on the package substrate and spaced apart from the first image sensor chip, and a dust trap on the package substrate and between the first image sensor chip and the second image sensor chip, wherein the dust trap is configured to capture foreign matter.

### CROSS-REFERENCE TO RELATED APPLICATION

This application claims priority under 35 U.S.C. 119 to Korean Patent Application No. 10-2025-0014331 filed on February 05, 2025, in the Korean Intellectual Property Office, the disclosure of which is incorporated by reference herein in its entirety.

### BACKGROUND

The present disclosure relates to an image sensor and a method for fabricating the same and, more particularly, to a complementary metal-oxide semiconductor (CMOS) type image sensor including a pixel separation pattern and a method for fabricating the same.

An image sensor is a type of semiconductor device that converts optical information into an electrical signal. Such an image sensor may include a charge-coupled device (CCD) image sensor and a complementary metal-oxide semiconductor (CMOS) image sensor.

An image sensor chip is an electronic component that may sense the intensity and color of an optical image to convert the optical image into digital image data, and store, transfer, and play back the image data. The image sensor chip may be a core components of a digital camera, a smartphone, an automobile, a security device, a robot, and the like.

To protect the image sensor chip, prevent external materials from entering an image region of the image sensor chip, and enable power supply and signal output between the image sensor chip and the substrate, the image sensor chip may be mounted on the device in the form of an image sensor package.

The image sensor chip may be configured in a package form, and when reflected light is incident on the image sensor, a ghost phenomenon or a flare phenomenon in which circular borders, light spreading, and light dots that do not actually exist are included in the image may occur. Therefore, flare may be prevented by forming a light-absorbing layer for preventing reflected light on an outer periphery of the image sensor chip.

### SUMMARY

One or more embodiments of the present disclosure provide an image sensor package which may have improved performance and yield.

One or more embodiments of the present disclosure also provide a method for fabricating an image sensor package which may have improved performance and yield.

According to an aspect of the disclosure, an image sensor package may include: a package substrate; a first image sensor chip on the package substrate; a second image sensor chip on the package substrate and spaced apart from the first image sensor chip; and a dust trap on the package substrate and between the first image sensor chip and the second image sensor chip, wherein the dust trap is configured to capture foreign matter.

According to an aspect of the disclosure, an image sensor package may include: a package substrate including a first surface and a second surface opposite the first surface; a first image sensor chip mounted on the first surface of the package substrate; a second image sensor chip mounted on the first surface of the package substrate and spaced apart from the first image sensor chip in a first direction; a dust trap between the first image sensor chip and the second image sensor chip; two fixing members between the first image sensor chip and the second image sensor chip, wherein the two fixing members are spaced apart in a second direction; a transparent cover spaced apart from upper portions of the first image sensor chip and the second image sensor chip in a third direction; and a dam interposed between the first image sensor chip and the transparent cover, wherein the dam is interposed between the second image sensor chip and the transparent cover, wherein the dam is configured to bond the first image sensor chip and the transparent cover, and wherein the dam is configured to bond the second image sensor chip and the transparent cover.

According to an aspect of the disclosure, an image sensor package may include: a package substrate including a first surface and a second surface opposite the first surface; a first image sensor chip mounted on the first surface of the package substrate; a second image sensor chip mounted on the first surface of the package substrate and spaced apart from the first image sensor chip in a first direction; an adhesive member between the first surface of the package substrate and both of the first image sensor chip and the second image sensor chip, wherein the adhesive member is configured to bond the package substrate to both of the first image sensor chip and the second image sensor chip; a dust trap between the first image sensor chip and the second image sensor chip; two fixing members between the first image sensor chip and the second image sensor chip, wherein the two fixing members are spaced apart in a second direction; a transparent cover spaced apart from upper portions of the first image sensor chip and the second image sensor chip in a third direction; a sealing member on the first surface of the package substrate, surrounding side surfaces of the first image sensor chip and the second image sensor chip, and surrounding side surfaces of the two fixing members; and a dam interposed between the first image sensor chip and the transparent cover, wherein the dam is interposed between the second image sensor chip and the transparent cover, wherein the dam is configured to bond the first image sensor chip and the transparent cover, wherein the dam is configured to bond the second image sensor chip and the transparent cover, wherein a thickness of the dust trap is less than a thickness of the first image sensor chip, wherein the thickness of the dust trap is less than a thickness of the second image sensor chip, wherein an uppermost surface of the two fixing members is coplanar with an uppermost surface of the first image sensor chip and the second image sensor chip, and wherein the image sensor package further includes a mask pattern in a portion of an upper surface of the transparent cover.

### BRIEF DESCRIPTION OF THE DRAWINGS

The above and other aspects and features will be more apparent from the following description of one or more example embodiments taken in conjunction with the attached drawings, in which:

FIG. 1 is a block diagram illustrating an image sensor according to one or more example embodiments.

FIG. 2 is a circuit diagram illustrating an image sensor according to one or more example embodiments.

FIG. 3 is a plan view illustrating an image sensor package according to one or more example embodiments.

FIG. 4 is a cross-sectional view taken along a line A-A’ of FIG. 3 according to one or more example embodiments.

FIG. 5 is a cross-sectional view taken along a line B-B’ of FIG. 3 according to one or more example embodiments.

FIG. 6 is a plan view illustrating an image sensor package according to one or more example embodiments.

FIG. 7 is a plan view illustrating an image sensor package according to one or more example embodiments.

FIG. 8 is a cross-sectional illustrating an image sensor package according to one or more example embodiments.

FIG. 9 is a plan view illustrating an image sensor package according to one or more example embodiments.

FIG. 10 is a plan view illustrating an image sensor package according to one or more example embodiments.

FIGS. 11, 12, 13, 14, 15, 16, 17, 18 and 19 are diagrams of intermediate structures corresponding to intermediate operations of a method for fabricating an image sensor package according to one or more example embodiments.

### DETAILED DESCRIPTION

Hereinafter, example embodiments will be described in detail with reference to the accompanying drawings. The same reference numerals are used for the same components in the drawings, and duplicate descriptions thereof are omitted.

As used herein, expressions such as “at least one of,” when preceding a list of elements, modify the entire list of elements and do not modify the individual elements of the list. For example, the expression, "at least one of a, b, or c," should be understood as including only a, only b, only c, both a and b, both a and c, both b and c, or all of a, b, and c.

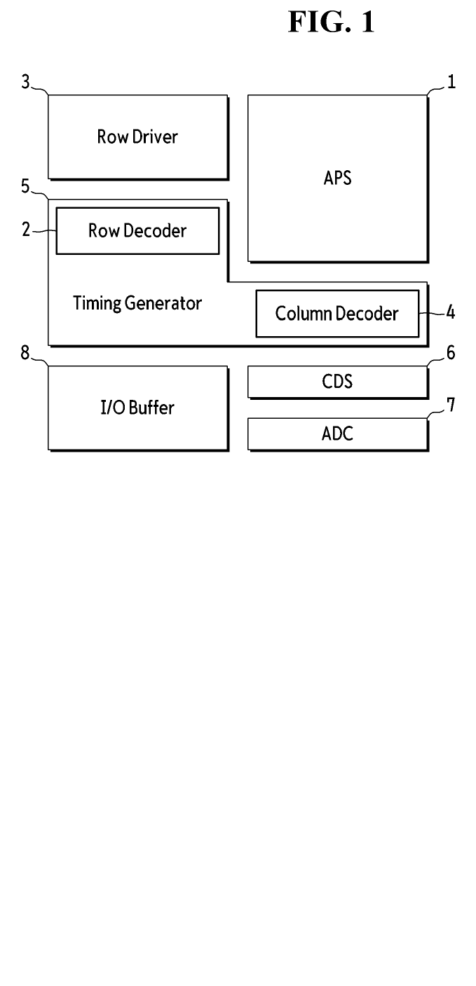

FIG. 1 is a block diagram illustrating an image sensor according to one or more example embodiments.

Referring to FIG. 1, the image sensor according to one or more example embodiments may include an active pixel sensor array (APS) 1, a row decoder 2, a row driver 3, a column decoder 4, a timing generator 5, a correlated double sampler (CDS) 6, an analog-to-digital converter (ADC) 7, and an input/output buffer (I/O Buffer) 8.

The active pixel sensor array 1 may include a plurality of unit pixels arranged two-dimensionally, and may convert optical signals into electrical signals. The active pixel sensor array 1 may be driven by a plurality of driving signals from the row driver 3, such as a pixel selection signal, a reset signal, and a charge transfer signal. Furthermore, the electrical signals converted by the active pixel sensor array 1 may be provided to the correlated double sampler 6.

The row driver 3 may provide the active pixel sensor array 1 with a plurality of driving signals for driving a plurality of unit pixels according to the results decoded in the row decoder 2. When the unit pixels are arranged in the form of a matrix, driving signals may be provided for each row.

The timing generator 5 may provide a timing signal and a control signal to the row decoder 2 and the column decoder 4.

The correlated double sampler (CDS) 6 may receive, hold and sample the electrical signals generated in the active pixel sensor array 1. The correlated double sampler 6 may doubly sample a specific noise level and a signal level due to an electric signal, and output a difference level corresponding to a difference between the noise level and the signal level.

The analog-to-digital converter (ADC) 7 may convert the analog signal corresponding to the difference level output from the correlated double sampler 6 into a digital signal and output the digital signal.

The input/output buffer 8 latches the digital signal, and the latched signal may sequentially output the digital signal to a video signal processing unit according to the decoding result from the column decoder 4.

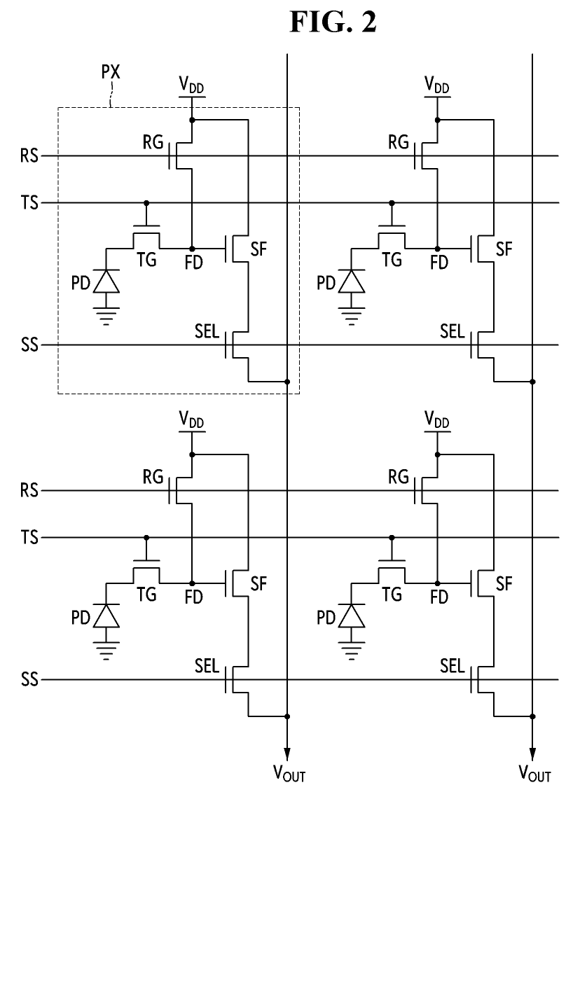

FIG. 2 is a circuit diagram illustrating an image sensor according to one or more example embodiments.

Referring to FIG. 2, the image sensor according to one or more example embodiments may include a plurality of unit pixels PX.

The plurality of unit pixels PX may be arranged two-dimensionally (e.g., in the form of a matrix). Each unit pixel PX may include a photoelectric conversion element PD, a transfer transistor TG, a floating diffusion region FD, a reset transistor RG, a drive transistor (source follower transistor) SF, and a selection transistor SEL.

The photoelectric conversion element PD may generate electric charges in proportion to the amount of light that is incident from the outside. The photoelectric conversion element PD may be coupled to the transfer transistor TG that transfers the generated and accumulated electric charges to the floating diffusion region FD. Because the floating diffusion region FD is a region for switching the electric charges into voltages, and has a parasitic capacitance, the electric charges may be accumulatively stored.

One end of the transfer transistor TG may be connected to the photoelectric conversion element PD, and the other end of the transfer transistor TG may be connected to the floating diffusion region FD. The transfer transistor TG may be formed of a transistor driven by a predetermined bias (e.g., the transfer signal TS). That is, the transfer transistor TG may transmit the electric charges generated from the photoelectric conversion element PD to the floating diffusion region FD according to the transfer signal TG.

The drive transistor SF may be provided as a source follower buffer amplifier. The drive transistor SF may amplify a change in the electric potential of the floating diffusion region FD that has received the electric charge from the photoelectric conversion element PD, and may output the amplified change to an output line V_{OUT}. When the drive transistor SF is turned on, a predetermined electrical potential, for example, a power supply voltage V_{DD}, provided to a drain of the drive transistor SF may be transferred to a drain region of the selection transistor SEL.

The selection transistor SEL may select a unit pixel PX to be read in units of a row. The selection transistor SX may comprise a transistor that is driven by a selection line that applies a predetermined bias (e.g., a row selection signal SS).

The reset transistor RG may periodically reset the floating diffusion region FD. The reset transistor RG may comprise a transistor that is driven by a reset line that applies a predetermined bias (e.g., a reset signal RS). When the reset transistor RG is turned on by the reset signal RS, a predetermined electrical potential provided to the drain of the reset transistor RG, for example, the power supply voltage V_{DD}, may be transferred to the floating diffusion region FD to reset the floating diffusion region FD.

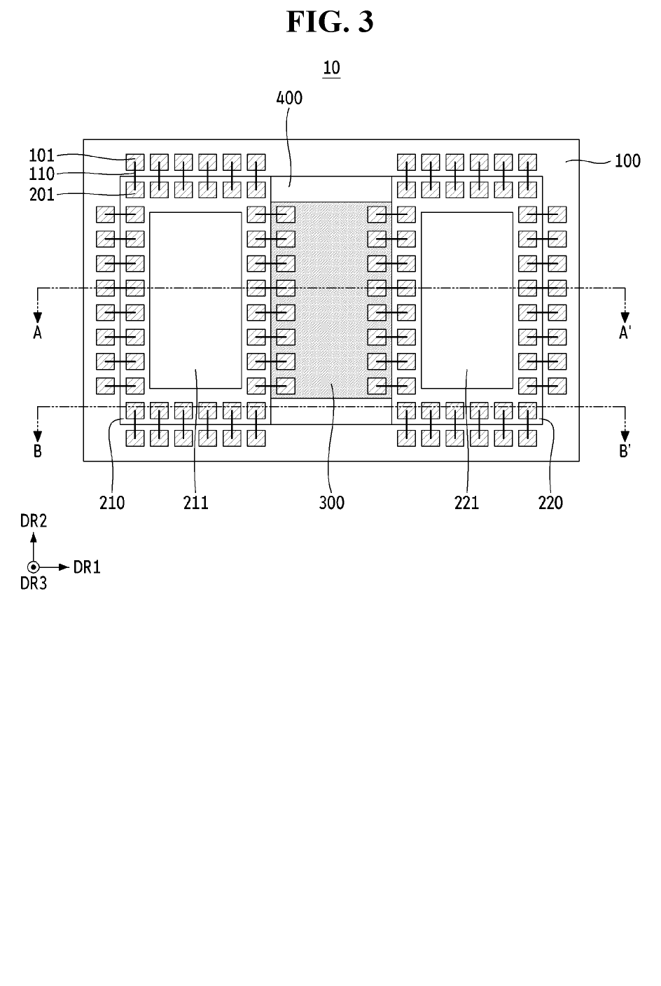

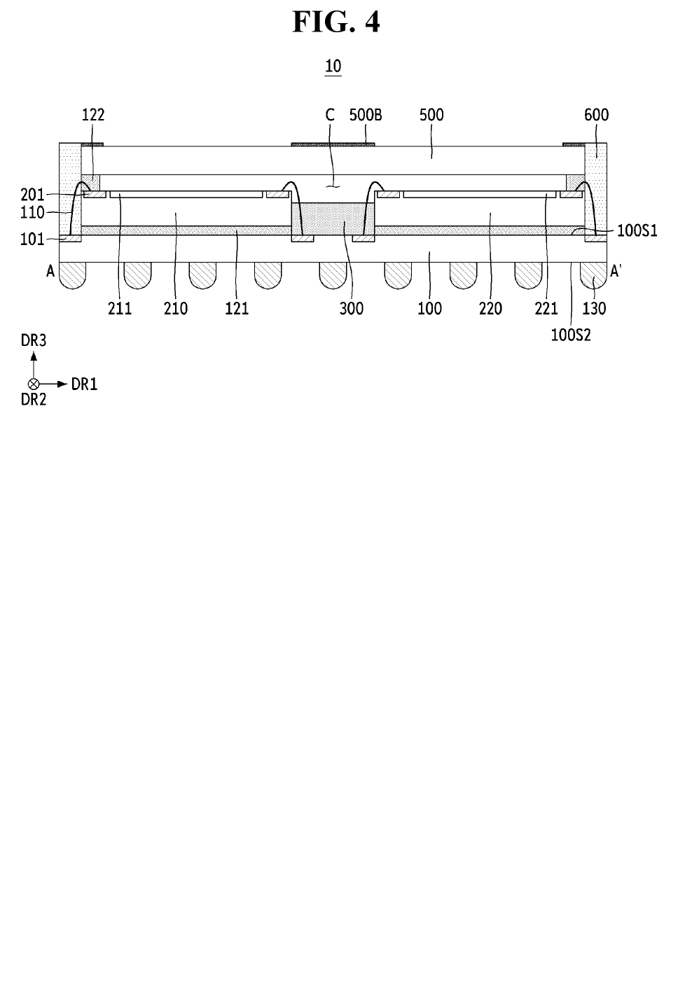

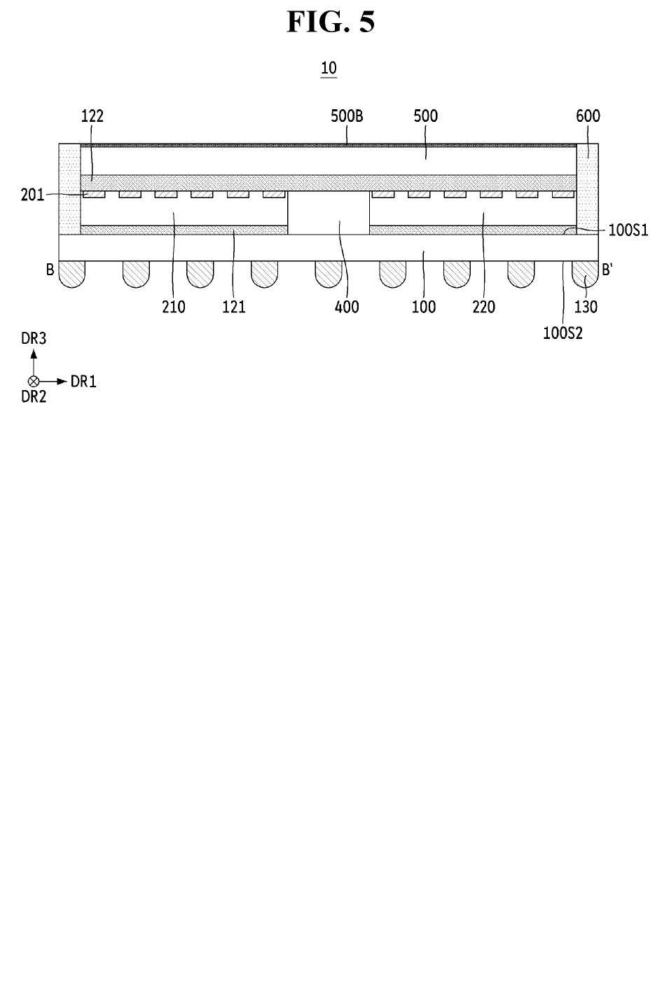

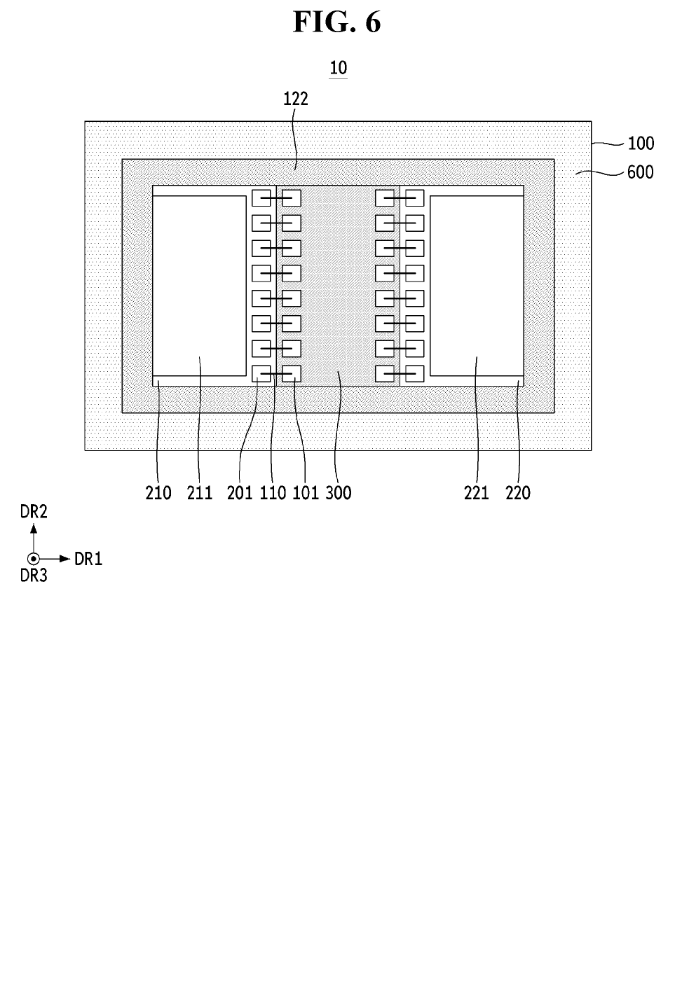

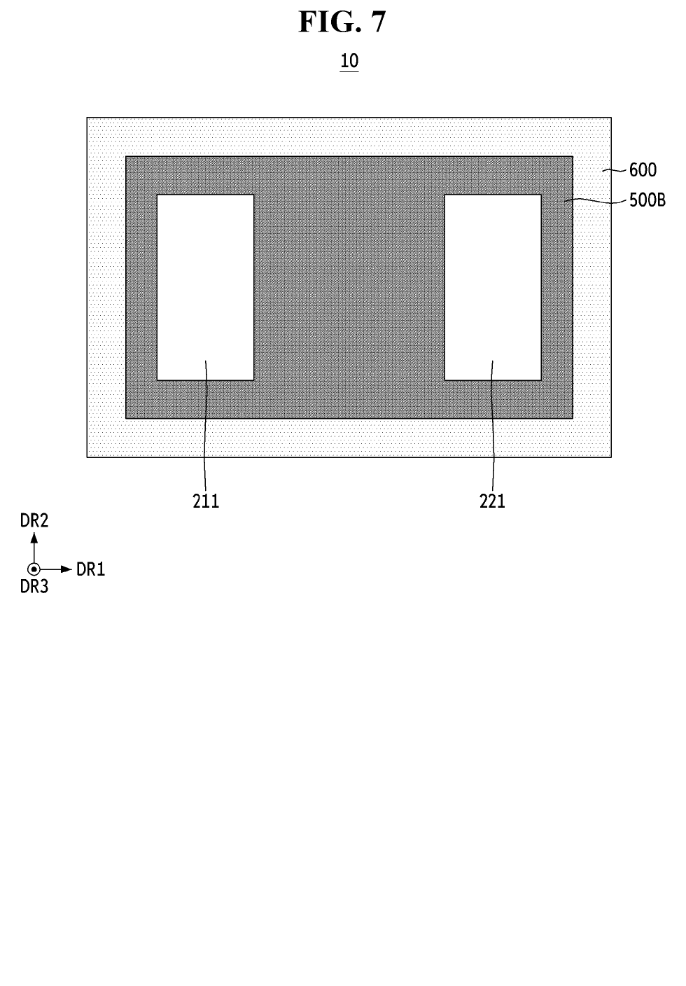

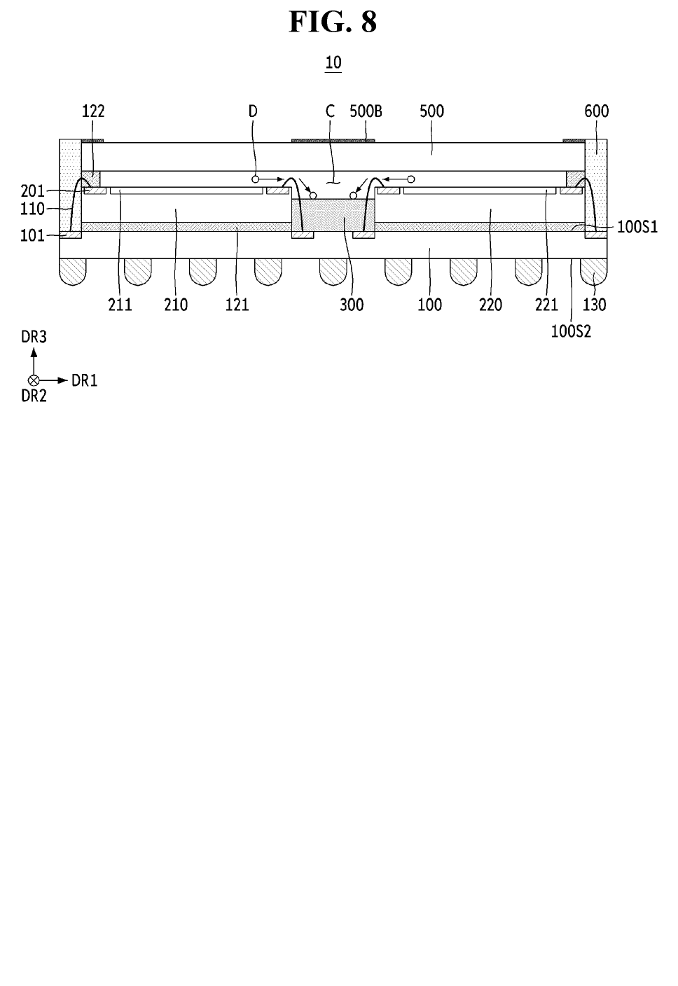

FIG. 3 is a plan view illustrating an image sensor package according to one or more example embodiments. FIG. 4 is a cross-sectional view taken along a line A-A’ of FIG. 3 according to one or more example embodiments. FIG. 5 is a cross-sectional view taken along a line B-B’ of FIG. 3 according to one or more example embodiments. FIG. 6 is a plan view illustrating an image sensor package according to one or more example embodiments. FIG. 7 is a plan view illustrating an image sensor package according to one or more example embodiments. FIG. 8 is a cross-sectional view illustrating the image sensor package according to one or more example embodiments.

Referring to FIGS. 3, 4, 5, 6, 7 and 8, an image sensor package 10 according to one or more example embodiments may include a package substrate 100, a connecting bump 130, image sensor chips 210 and 220, a dam 122, a transparent cover 500, and a sealing member 600.

In one or more example embodiments, the semiconductor package may be a multi-chip package (MCP) including different types of semiconductor chips. The semiconductor package may be a system-in-package (SIP) in which a plurality of semiconductor chips are stacked or arranged in a single package and have one independent function.

The package substrate 100 may be a semiconductor substrate. For example, the package substrate 100 may be bulk silicon or silicon-on-insulator (SOI). The package substrate 100 may be a silicon substrate, or may include other materials, for example, silicon germanium, indium antimonide, a lead tellurium compound, indium arsenic, indium phosphide, gallium arsenide or gallium antimonide. Alternatively, the package substrate 100 may have an epitaxial layer formed on a base substrate.

The package substrate 100 may include a first surface 100S1 and a second surface 100S2 that are opposite to each other. In one or more example embodiments to be described in greater detail below, the first surface 100S1 of the package substrate 100 may be referred to as an upper surface of the package substrate 100, and the second surface 100S2 of the package substrate 100 may be referred to as a lower surface of the package substrate 100. The substrate pad 101 may be disposed on the first surface 100S1 of the package substrate 100. According to one or more example embodiments, the substrate pad 101 may also be disposed on the second surface 100S2 of the package substrate 100. The substrate pad 101 on the first surface 100S1 and the substrate pad on the second surface 100S2 may be electrically connected to each other.

According to one or more example embodiments, the package substrate 100 may include a plurality of wiring patterns and an insulating layer. Each of the plurality of wiring patterns may include a horizontal wiring portion and a via wiring portion. The via wiring portion may be a portion for vertical (e.g., a third direction DR3) connection, and the horizontal wiring portion may be a portion for horizontal (e.g., a first direction DR1 or a second direction DR2) connection. The insulating layer may include, as a thermosetting resin, an epoxy resin, a polyimide resin, a Bismaleimide Triazine (BT) resin, a Teflon resin or the like. The insulating layer may include an insulating polymer or a photo imageable polymer (PID). For example, the photo imageable polymer may include at least one of a photosensitive polyimide, a polybenzoxazole (PBO), a phenol-based polymer, or a benzocyclobutene-based polymer.

The image sensor chips 210 and 220 may be disposed on the package substrate 100. The image sensor chips 210 and 220 may be disposed on the first surface 100S1 of the package substrate 100. The image sensor chips 210 and 220 may be mounted on the package substrate 100 through bonding wires 110. Specifically, the package substrate 100 may include a plurality of substrate pads 101 disposed on the first surface 100S1. The first and second image sensor chips 210 and 220 may include a plurality of chip pads 201 disposed on the upper surfaces of the first and second image sensor chips 210 and 220. The bonding wires 110 may electrically connect the substrate pads 101 and the chip pads 201. The bonding wires 110 may be formed of, for example, gold (Au), copper (Cu), silver (Ag), aluminum (Al), etc.

The image sensor chips 210 and 220 may include an active surface and a non-active surface. The active surfaces of the image sensor chips 210 and 220 may face upward, and the non-active surfaces may face the first surface 100S1 of the lower package substrate 100.

The image sensor chips 210 and 220 may be adhesively fixed to the first surface 100S1 of the package substrate 100 through an adhesive member 121. The adhesive member 121 may be interposed between the package substrate 100 and the image sensor chips 210 and 220. The adhesive member 121 may bond the package substrate 100 to the first and second image sensor chips 210 and 220. The adhesive member 121 may play a role of not only bonding the image sensor chips 210 and 220 on the package substrate 100, but also of relieving the impact applied to the image sensor chips 210 and 220 when an external impact is applied.

The adhesive member 121 may include epoxy resin, polyimide, etc. An epoxy-series adhesive may be used for strong bonding between the chip and the substrate in the die bonding process. For example, the die epoxy has excellent adhesive strength, insulating properties, and thermal stability, and may improve the safety of the semiconductor package.

The image sensor chips 210 and 220 may include a chip pad 201 and sensor units 211 and 221. According to one or more example embodiments, the image sensor chips 210 and 220 may each include a chip body. The chip body may include a substrate and a wiring layer of the image sensor chips 210 and 220. The substrate may be formed of, for example, a silicon bulk wafer, an epitaxial wafer or the like. The epitaxial wafer may include a crystalline material layer grown on a bulk substrate by an epitaxial process, i.e., an epitaxial layer. The substrate is not limited to a bulk wafer or an epitaxial wafer, and, according to one or more example embodiments, may be formed, using various wafers such as a polished wafer, an annealed wafer, and a Silicon On Insulator (SOI) wafer. The wiring layer may be formed on either surface of the substrate. For example, the wiring layer may be disposed below the sensor units 211 and 221.

The sensor units 211 and 221 may include a pixel region or an active pixel sensor (APS) region having a plurality of pixels. The pixels in the pixel region may be disposed in a two-dimensional array structure. Furthermore, each of the pixels of the pixel region may include a photodiode formed in the substrate. The photodiode may be formed through an ion implantation process in which impurity ions are implanted in the pixel region. Each pixel of the pixel region may absorb the incident light, generate and accumulate electric charges corresponding to the amount of light, and transfer the accumulated electric charges to the outside through a pixel transistor. The pixel transistor may include, for example, a transfer transistor, a source follower transistor, a reset transistor, a selection transistor and the like. Meanwhile, the sensor units 211 and 221 may include a color filter and a microlens. As apparent from FIG. 3, the sensor units 211 and 221 may be disposed in the central portions of the image sensor chips 210 and 220.

The chip pad 201 may be disposed in a peripheral region of the image sensor chips 210 and 220. The peripheral region may refer to an outer periphery of the image sensor chips 210 and 220 that surround the sensor units 211 and 221. Referring to FIG. 3, a plurality of chip pads 201 may be disposed along the first direction DR1 and the second direction DR2 in the outer periphery of the image sensor chips 210 and 220 that surround the sensor units 211 and 221. According to one or more example embodiments, the chip pad 201 may be electrically connected to a wiring layer inside the image sensor chips 210 and 220. The chip pad 201 may be electrically connected to a corresponding substrate pad 101 of the package substrate 100 through the bonding wire 110.

Referring to FIG. 3, in one or more example embodiments, the image sensor package 10 may include two image sensor chips 210 and 220 inside the single package. The first image sensor chip 210 may be mounted on the first surface 100S1 of the package substrate 100. The second image sensor chip 220 may be mounted on the first surface 100S1 of the package substrate 100, and may be disposed to be spaced apart from the first image sensor chip 210 in the first direction DR1. Two image sensor chips 210 and 220 may be mounted inside the single image sensor package 10 to manufacture an optical angle CMOS Image Sensor (CIS) package.

A dust trap 300 may be disposed between the first image sensor chip 210 and the second image sensor chip 220. The dust trap 300 may be disposed on the first surface 100S1 of the package substrate 100. The dust trap 300 may cover a portion of the substrate pad 101 and the bonding wire 110. Specifically, the dust trap 300 may cover the substrate pad 101 disposed between the first and second image sensor chips 210 and 220 and a portion of the bonding wire 110 connected thereto. A thickness of the dust trap 300 may be less than the thickness of the image sensor chips 210 and 220. A height of the dust trap 300 in the third direction DR3 may be less than height of the first and second image sensor chips 210 and 220 in the third direction DR3. The third direction DR3 is a direction perpendicular to both the first direction DR1 and the second direction DR2. The dust trap 300 may include an epoxy resin. The dust trap 300 may provide adhesive strength.

Referring to FIG. 3, the two fixing members 400 may be disposed to be spaced apart on both sides of the dust trap 300. Specifically, the fixing members 400 may be disposed between the first image sensor chip 210 and the second image sensor chip 220 to be spaced apart in the second direction DR2. The fixing members 400 may be in contact with a portion of the side walls of the first and second image sensor chips 210 and 220. The fixing members 400 may be in contact with both side walls of the dust trap 300 spaced apart in the second direction. The uppermost surface of the fixing member 400 may be coplanar with the upper surfaces of the first and second image sensor chips 210 and 220. The fixing member 400 may include glass, but this is an example embodiment, and the material included in the fixing member is not limited to this example embodiment. The fixing member 400 may be in contact with the dust trap 300 and may fix the dust trap 300.

FIG. 4 is a cross-sectional view taken along the line A-A’ of FIG. 3 according to one or more example embodiments. FIG. 5 is a cross-sectional view taken along the line B-B’ of FIG. 4 according to one or more example embodiments. Referring to FIGS. 4 and 5, the transparent cover 500 may be disposed on the first and second image sensor chips 210 and 220. Specifically, the transparent cover 500 may be disposed to be spaced apart from the upper portions of the first and second image sensor chips 210 and 220 in the third direction DR3. In one or more example embodiments, the transparent cover 500 may include transparent glass, but this is an example embodiment, and the transparent cover 500 is not limited to this example embodiment. In one or more example embodiments, the transparent cover 500 may include a transparent resin, a translucent ceramic, etc.

Referring to FIG. 7, a mask pattern 500B may be disposed in a portion of the upper surface of the transparent cover 500. Specifically, the mask pattern 500B may be disposed in a portion except the place in which the sensor units 211 and 221 are located in a plane formed by the first direction DR1 and the second direction DR2. The mask pattern 500B may include an ink composition. The ink composition may include a low molecule, a high molecule or an organic material. For example, the mask pattern 500B may include a photosensitive material including a black pigment. The mask pattern 500B may prevent a flare phenomenon inside the image sensor package 10.

The dam 122 may be interposed between the first and second image sensor chips 210 and 220 and the transparent cover 500. The dam 122 may bond the first and second image sensor chips 210 and 220 and the transparent cover 500. The transparent cover 500 may be disposed on the dam 122 formed on the upper surface of the image sensor chips 210 and 220. Accordingly, the transparent cover 500 may be disposed to be spaced apart from the image sensor chips 210 and 220 by the height of the dam 122. Thus, a cavity C portion sealed by the dam 122 may be formed between the transparent cover 500 and the image sensor chips 210 and 220. The upper surfaces of the first and second image sensor chips 210 and 220 and the upper surface of the dust trap 300 may be exposed to the cavity C portion.

The dam 122 may support the transparent cover 500. In addition, the dam 122 may seal the cavity C portion to prevent moisture or foreign matter from entering the cavity C portion from the outside, thereby preventing contamination of the image sensor chips 210 and 220, particularly the sensor units 211 and 221. The dam 122 may be disposed on the upper surfaces of the image sensor chips 210 and 220 and on the upper surface of the fixing member 400. Referring to FIG. 6, the dam 122 may be disposed to have a rectangular ring shape in an outermost partial region of the upper surfaces of the first and second image sensor chips 210 and 220 and on the upper surface of the fixing member 400. As the dam 122 is disposed in the outermost partial region of the upper surfaces of the image sensor chips 210 and 220, the dam 122 may cover the chip pads 201 disposed on the upper surfaces of the image sensor chips 210 and 220 and a portion of the bonding wires 110 connected thereto.

The dam 122 may be formed of an appropriate material in consideration of the stress of the bonding wire 110, the physical properties of the sealing member 600, and the like. For example, the dam 122 may be formed of a glue adhesive, but this is an example embodiment, and the material of the dam 122 is not limited to this example embodiment. The dam 122 may include epoxy resin, polyimide, and the like, similar to the adhesive member 121.

The sealing member 600 may be disposed on the package substrate 100. The sealing member 600 may surround the side surfaces of the first and second image sensor chips 210 and 220 and the side surface of the fixing member 400. Specifically, the sealing member 600 may cover the first surface 100S1 of the package substrate 100, the image sensor chips 210 and 220, the fixing member 400, the dam 122, and the side surface of the transparent cover 500. The sealing member 600 may also cover the substrate pads 101 and a portion of the bonding wires 110 connected thereto.

Referring to FIGS. 4 and 5, the upper surface of the sealing member 600 may be coplanar with the upper surface of the mask pattern 500B on the transparent cover 500. However, according to one or more example embodiments, the upper surface of the sealing member 600 may have a slight slope with the upper surface of the mask pattern 500B. The sealing member 600, together with the dam 122, may prevent the sensor units 211 and 221 of the image sensor chips 210 and 220 from being contaminated by external foreign matter. In addition, the sealing member 600 may protect the image sensor package 10 from external impact. The sealing member 600 may be formed of an Epoxy Molding Compound (EMC). However, this is merely an example embodiment, and the material of the sealing member 600 is not limited to this example embodiment.

FIG. 8 is a cross-sectional view illustrating an image sensor package according to one or more example embodiments

Referring to FIG. 8, foreign matter D may float in the cavity C portion inside the image sensor package 10. The foreign matter D floating in the cavity C portion may cause a defect inside the package. The dust trap 300 disposed between the first and second image sensor chips 210 and 220 may capture the foreign matter D floating in the cavity C portion. As the dust trap 300 captures the foreign matter D, the foreign matter D floating in the cavity C portion decreases, and defects of the image sensor chips 210 and 220 may be prevented.

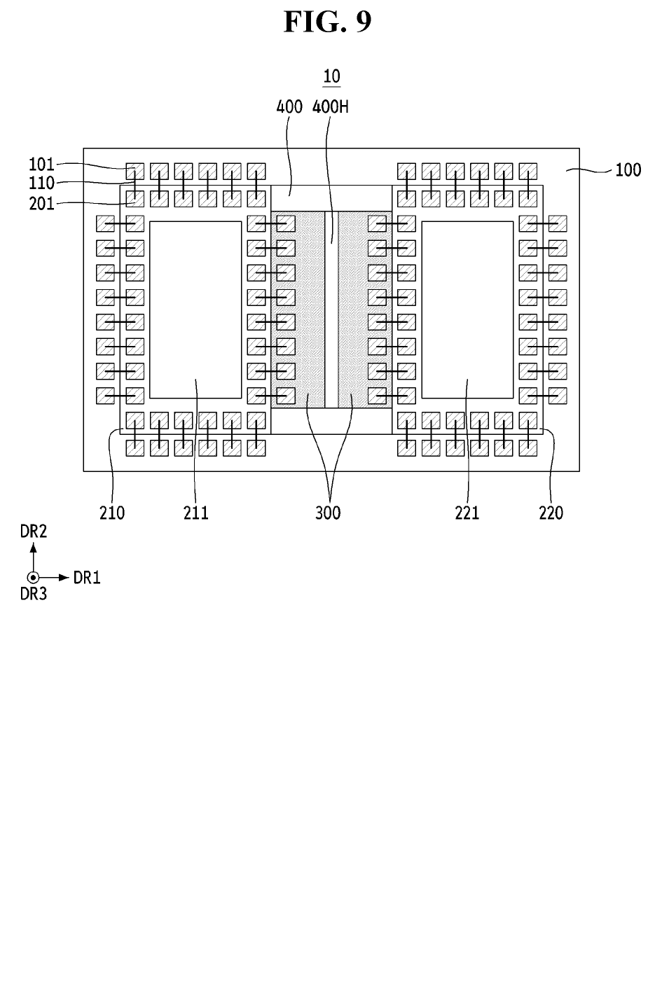

FIG. 9 is a plan view illustrating an image sensor package according to one or more example embodiments.

Referring to FIG. 9, the image sensor package according to one or more example embodiments may include a fixing auxiliary member 400H. The fixing auxiliary member 400H may be disposed to extend in the second direction DR2 between the two fixing members 400. The fixing auxiliary member 400H may be in contact with the two fixing members 400. The fixing auxiliary member 400H may be disposed in contact with the fixing member 400 and may relieve an impact when an impact occurs from the outside.

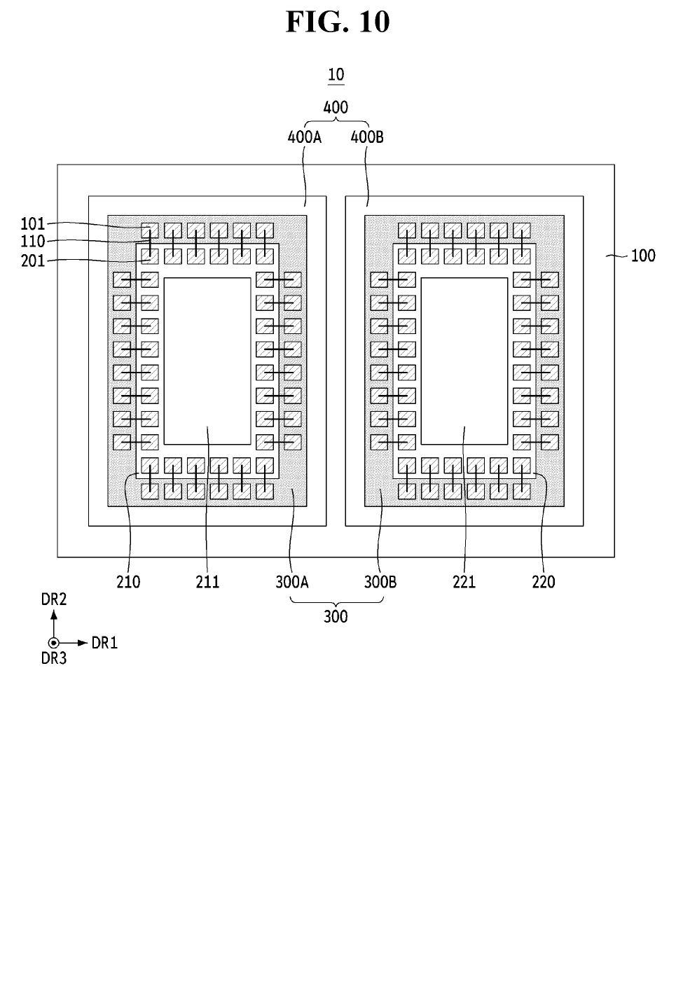

FIG. 10 is a plan view illustrating an image sensor package according to one or more example embodiments.

Referring to FIG. 10, the dust trap 300 may include first and second dust traps 300A and 300B. The fixing member 400 may include first and second fixing members 400A and 400B. The first dust trap 300A may be disposed to surround the first image sensor chip 210. The second dust trap 300B may be disposed to surround the second image sensor chip 220. The first fixing member 400A may be disposed to surround the first dust trap 300A. The second fixing member 400B may be disposed to surround the second dust trap 300A. Although the dust traps 300A and 300B and the fixing members 400A and 400B are shown as a rectangular shape according to an example embodiment, the shapes of the dust traps 300A and 300B and the fixing members 400A and 400B are not limited to this example embodiment. According to one or more example embodiments, the thickness of the first and second dust traps 300A and 300B may be less than that of the first and second image sensor chips 210 and 220. The uppermost surfaces of the first and second fixing members 400A and 400B may be coplanar with the uppermost surfaces of the first and second image sensor chips 210 and 220.

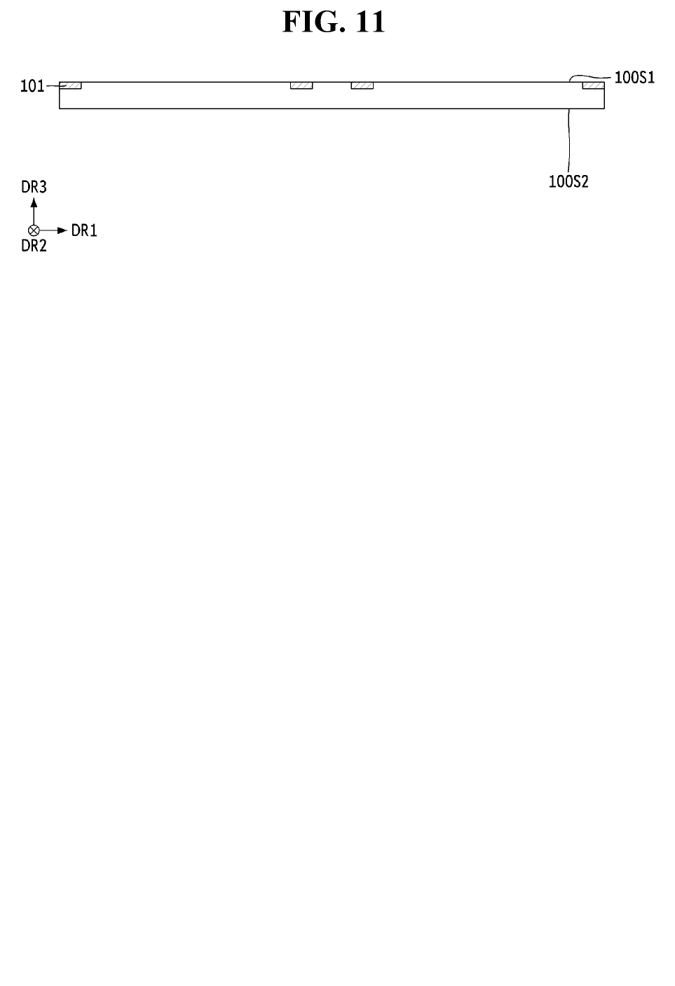

FIGS. 11, 12, 13, 14, 15, 16, 17, 18 and 19 are diagrams of intermediate structures corresponding to intermediate operations of a method for fabricating an image sensor package according to one or more example embodiments.

Referring to FIG. 11, the package substrate 100 may include a first surface 100S1 and a second surface 100S2 that are opposite to each other. At least one or more substrate pad 101 may be disposed on the first surface 100S1 of the package substrate 100.

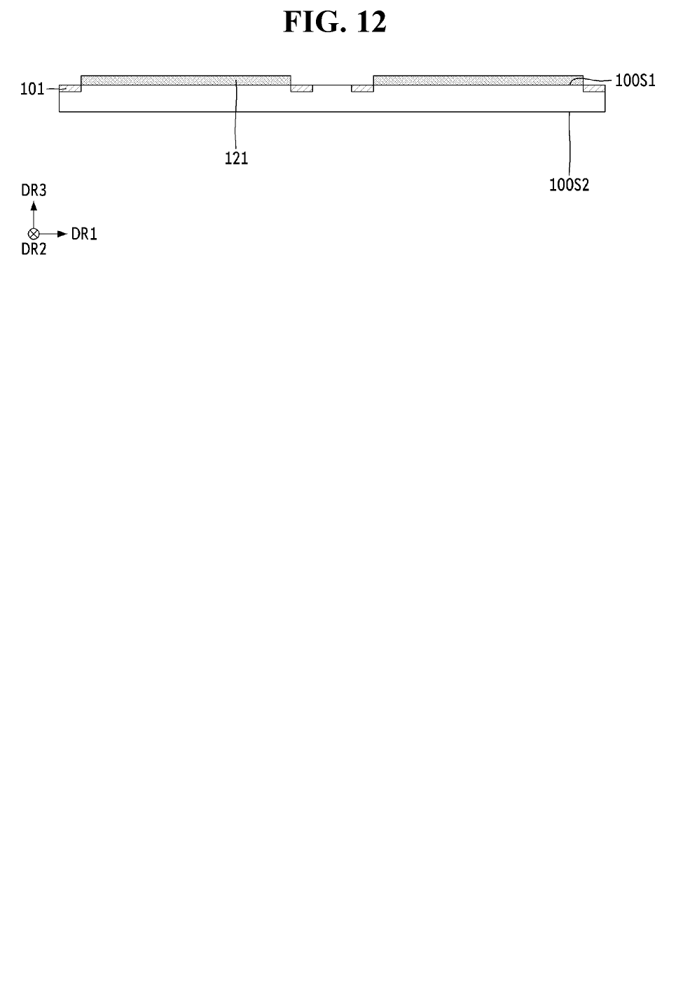

Referring to FIG. 12, an adhesive member 121 may be applied on the package substrate 100. The adhesive member 121 may be disposed on the first surface 100S1 of the package substrate 100.

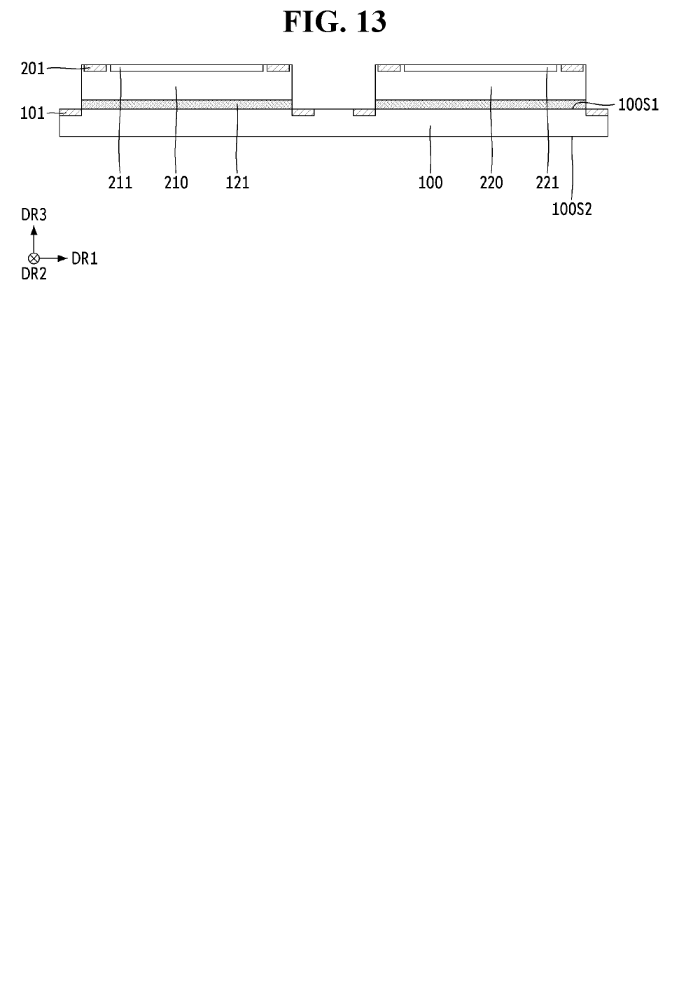

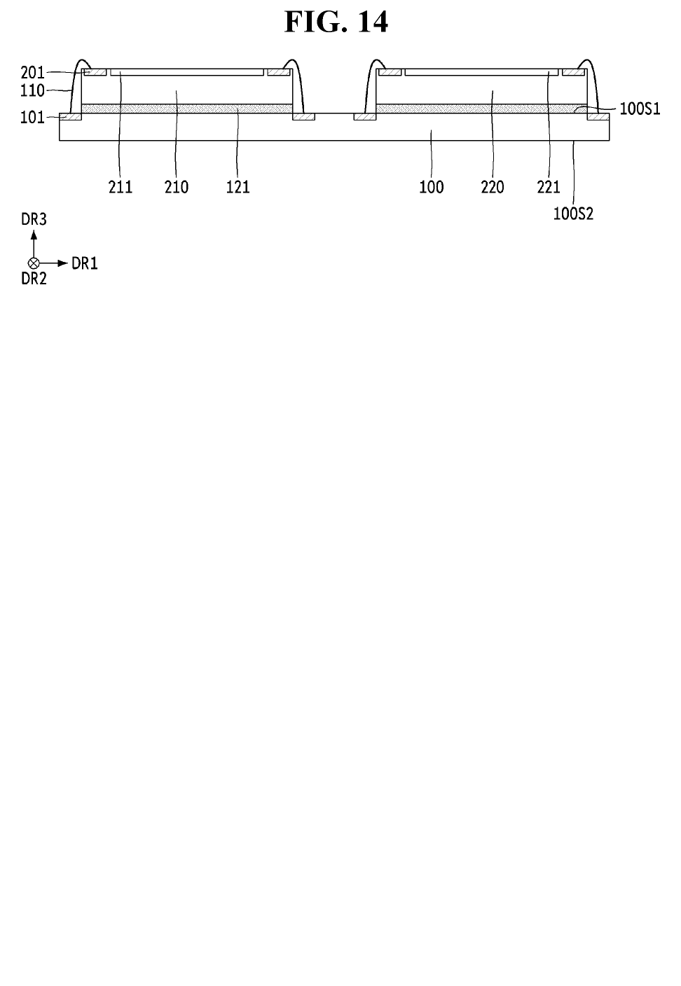

Referring to FIGS. 13 and 14, the first and second image sensor chips 210 and 220 may be mounted on the package substrate 100. The first and second image sensor chips 210 and 220 may be bonded on the package substrate 100 by the adhesive member 121. The bonding wires 110 may electrically connect the substrate pad 101 on the package substrate 100 and the chip pads 201 of the image sensor chips 210 and 220. The image sensor chips 210 and 220 may be mounted on the first surface 100S1 of the package substrate 100 through the bonding wires 110.

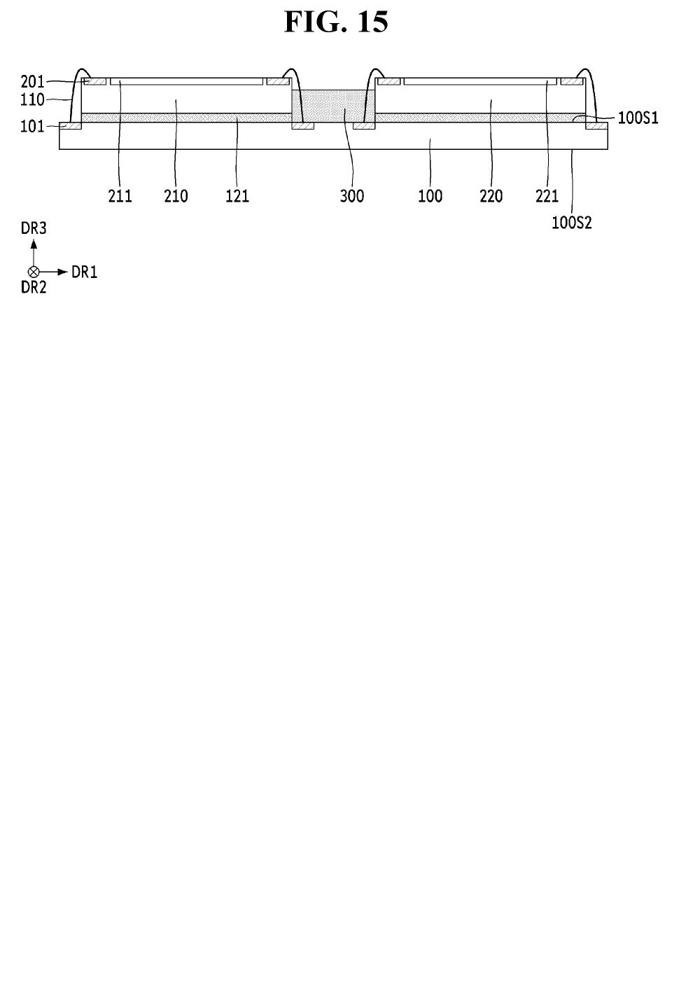

Referring to FIG. 15, two fixing members 400 may be disposed between the first and second image sensor chips 210 and 220 of the package substrate 100. After the two fixing members 400 are disposed, the dust trap 300 may be disposed between the first and second image sensor chips 210 and 220. The dust trap 300 may be disposed between the first and second image sensor chips 210 and 220 disposed to be spaced apart in the first direction DR1. The dust trap 300 may be disposed between two fixing members 400 disposed to be spaced apart in the second direction DR2. The thickness of the dust trap 300 is disposed to be less than the thickness of the first and second image sensor chips 210 and 220.

After the operation of disposing the dust trap 300, the dust trap 300 may be cured. The curing may be performed at a temperature in the range of 120°C to 150°C.

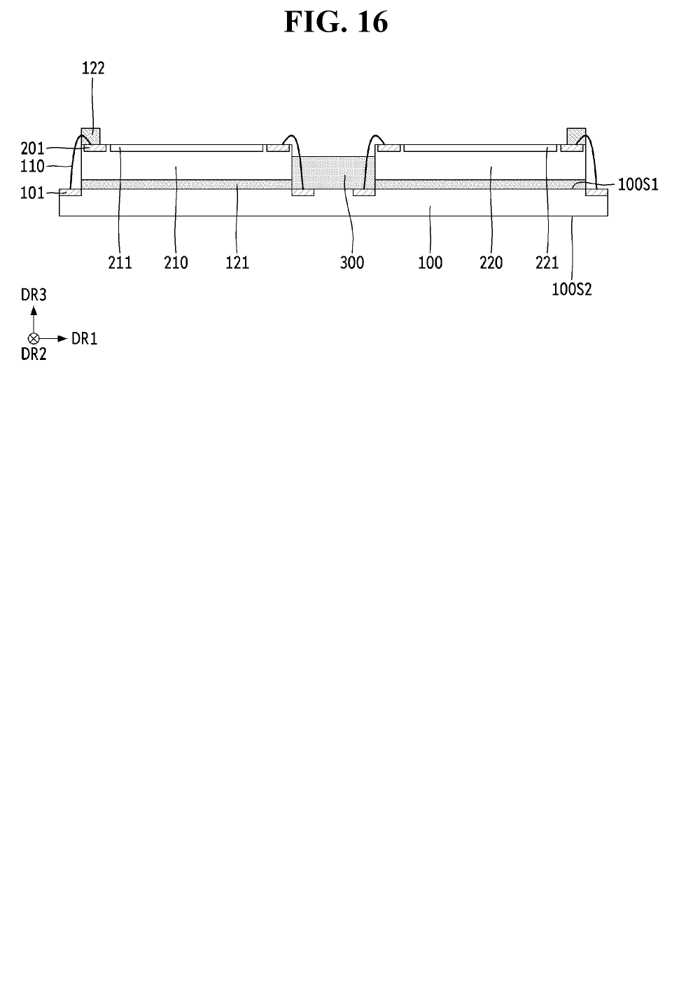

Referring to FIG. 16, a dam 122 may be applied to a portion of the upper surfaces of the first and second image sensor chips 210 and 220 and the upper surface of the fixing member 400. According to one or more example embodiments, the dam 122 may be disposed in the form of a square ring, but one or more example embodiments are not limited thereto.

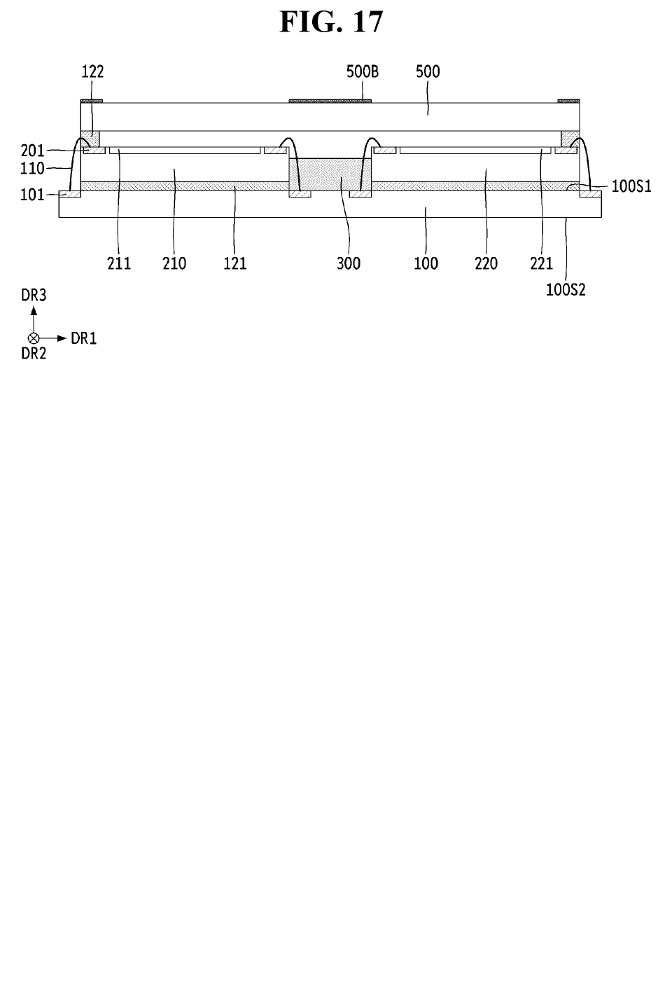

Referring to FIG. 17, a transparent cover 500 spaced apart from the upper portion of the first and second image sensor chips 210 and 220 may be attached on the dam 122. The transparent cover 500 may include the mask pattern 500B in a portion of the upper surface.

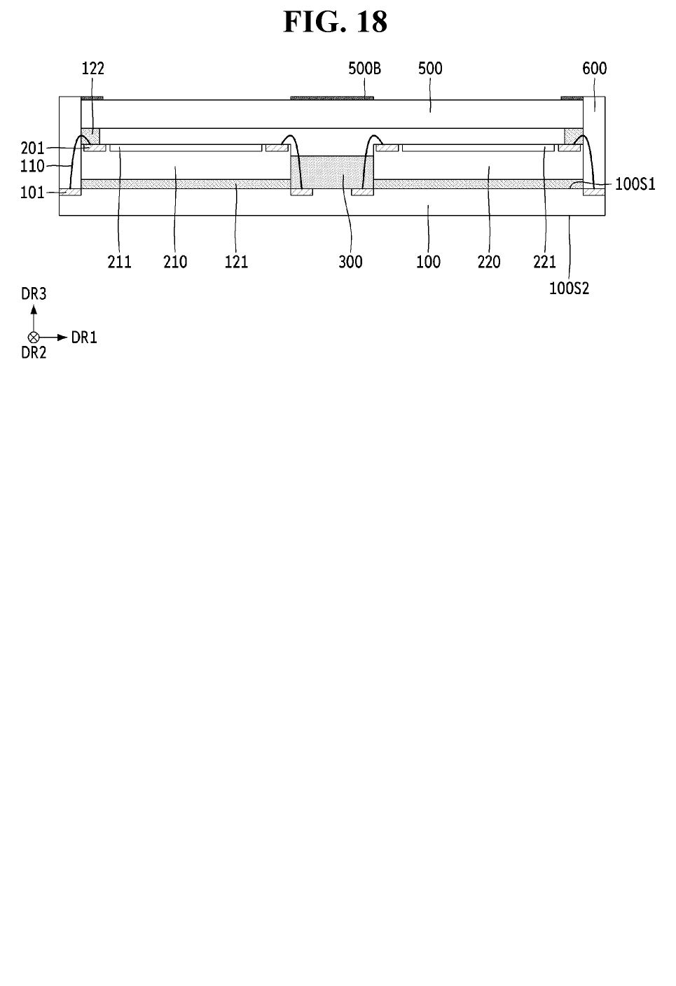

Referring to FIG. 18, the sealing member 600 that seals the first and second image sensor chips 210 and 220 and covers the surface face of the transparent cover 500 may be disposed on the package substrate 100.

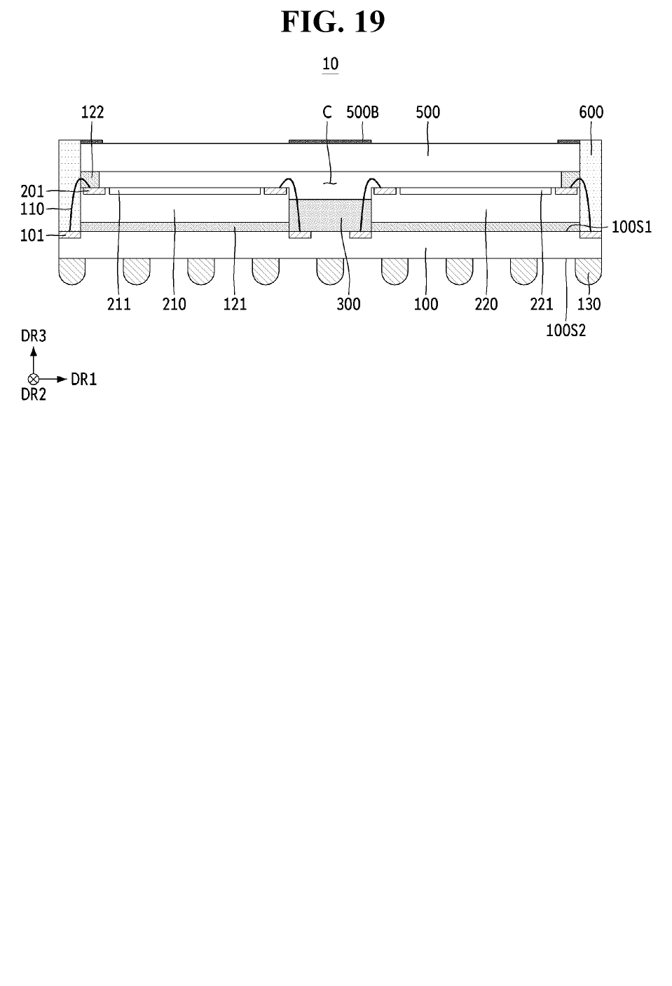

Referring to FIG. 19, the connecting bump 130 may be disposed on the second surface 100S2 of the package substrate 100. At least one or more connecting bump 130 may be disposed on the second surface 100S2 of the package substrate 100. According to one or more example embodiments, the connecting bump 130 may have a shape of a solder ball, but one or more example embodiments are not limited thereto. Each of the plurality of connecting bumps 130 may have a shape of a land, a ball or a pin. According to one or more example embodiments, the number, interval, placement form or the like of the connecting bumps 130 are not limited to those example embodiments shown in the drawings and may vary depending on the design. The connecting bump 130 may include a conductive material, for example, nickel (Ni), copper (Cu), palladium (Pd), platinum (Pt), gold (Au), tin (Sn), indium (In), bismuth (Bi), antimony (Sb), copper (Cu), silver (Ag), zinc (Zn), lead (Pb) or an alloy thereof. The connecting bump 130 may provide a connection path that electrically connects the image sensor package 10 to the outside.

According to an aspect of the disclosure, a method of manufacturing an image sensor package may include: providing a package substrate; providing a first image sensor chip on the package substrate; providing a second image sensor chip on the package substrate spaced apart from the first image sensor chip; and providing a dust trap on the package substrate and between the first image sensor chip and the second image sensor chip, wherein the dust trap is configured to capture foreign matter.

According to an aspect of the disclosure, the method of manufacturing the image sensor package may further include providing two fixing members spaced apart from each other and on opposite sides of the dust trap, wherein the two fixing members are configured to fix the dust trap.

According to an aspect of the disclosure, the method of manufacturing the image sensor package may be implemented wherein a thickness of the dust trap to be less than a thickness of the first image sensor chip, and wherein the thickness of the dust trap is less than a thickness of the second image sensor chip.

According to an aspect of the disclosure, the method of manufacturing the image sensor package may be implemented wherein an uppermost surface of the two fixing members is coplanar with an uppermost surface of the first image sensor chip and the second image sensor chip.

According to an aspect of the disclosure, the method of manufacturing the image sensor package may further include providing a sealing member on the package substrate, surrounding side surfaces of the first image sensor chip and the second image sensor chip, and surrounding side surfaces of the two fixing members.

According to an aspect of the disclosure, the method of manufacturing the image sensor package may further include providing a transparent cover on the first image sensor chip and the second image sensor chip.

According to an aspect of the disclosure, the method of manufacturing the image sensor package may further include providing a mask pattern in a portion of an upper surface of the transparent cover.

According to an aspect of the disclosure, the method of manufacturing the image sensor package may further include providing a dam interposed between the first image sensor chip and the transparent cover, wherein the dam is also interposed between the second image sensor chip and the transparent cover, wherein the dam is configured to bond the first image sensor chip and the transparent cover, and wherein the dam is configured to bond the second image sensor chip and the transparent cover.

According to an aspect of the disclosure, the method of manufacturing the image sensor package may be implemented wherein the dam is in a portion of upper surfaces of the first image sensor chip and the second image sensor chip.

According to an aspect of the disclosure, the method of manufacturing the image sensor package may be implemented wherein a cavity portion sealed by the dam is formed between the first image sensor chip and the transparent cover and between the second image sensor chip and the transparent cover, and wherein upper surfaces of the first image sensor chip and the second image sensor chip, and an upper surface of the dust trap, are exposed to the cavity portion.

According to an aspect of the disclosure, the method of manufacturing the image sensor package may be implemented wherein the package substrate comprises a first surface and a second surface opposite the first surface, wherein the package substrate includes: at least one substrate pad on the first surface; and at least one connecting bump on the second surface, wherein the first image sensor chip and the second image sensor chip comprise at least one chip pad disposed on at least one upper surface of the first image sensor chip and the second image sensor chip.

According to an aspect of the disclosure, the method of manufacturing the image sensor package may further include providing at least one bonding wire that electrically connects the at least one substrate pad and the at least one chip pad.

According to an aspect of the disclosure, the method of manufacturing the image sensor package may be implemented wherein the first image sensor chip and the second image sensor chip are mounted on the first surface of the package substrate using the at least one bonding wire.

According to an aspect of the disclosure, the method of manufacturing the image sensor package may further include providing an adhesive member between the package substrate and both of the first image sensor chip and the second image sensor chip, wherein the adhesive member is configured to bond the package substrate to both of the first image sensor chip and the second image sensor chip.

Although one or more example embodiments have been particularly shown and described above, the present disclosure is not limited to the above one or more example embodiments and it will be apparent to those skilled in the art that various changes in form and details may be made therein without departing from the spirit and scope of the following claims.

What is claimed is:

1. An image sensor package comprising:
a package substrate;
a first image sensor chip on the package substrate;
a second image sensor chip on the package substrate and spaced apart from the first image sensor chip; and
a dust trap on the package substrate and between the first image sensor chip and the second image sensor chip,
wherein the dust trap is configured to capture foreign matter.

2. The image sensor package of claim 1, further comprising:
two fixing members spaced apart from each other and on opposite sides of the dust trap,
wherein the two fixing members are configured to fix the dust trap.

3. The image sensor package of claim 2, wherein a thickness of the dust trap is less than a thickness of the first image sensor chip, and
wherein the thickness of the dust trap is less than a thickness of the second image sensor chip.

4. The image sensor package of claim 2, wherein an uppermost surface of the two fixing members is coplanar with an uppermost surface of the first image sensor chip and the second image sensor chip.

5. The image sensor package of claim 2, further comprising:
a sealing member on the package substrate, surrounding side surfaces of the first image sensor chip and the second image sensor chip, and surrounding side surfaces of the two fixing members.

6. The image sensor package of claim 1, further comprising:
a transparent cover on the first image sensor chip and the second image sensor chip.

7. The image sensor package of claim 6, further comprising:
a mask pattern in a portion of an upper surface of the transparent cover.

8. The image sensor package of claim 6, further comprising:
a dam interposed between the first image sensor chip and the transparent cover,
wherein the dam is also interposed between the second image sensor chip and the transparent cover, and
wherein the dam is configured to bond the first image sensor chip and the transparent cover, and bond the second image sensor chip and the transparent cover.

9. The image sensor package of claim 8, wherein the dam is in a portion of upper surfaces of the first image sensor chip and the second image sensor chip.

10. The image sensor package of claim 8, wherein a cavity portion sealed by the dam is formed between the first image sensor chip and the transparent cover and between the second image sensor chip and the transparent cover, and
wherein upper surfaces of the first image sensor chip and the second image sensor chip, and an upper surface of the dust trap, are exposed to the cavity portion.

11. The image sensor package of claim 1, wherein the package substrate comprises a first surface and a second surface opposite the first surface,
wherein the package substrate comprises:
at least one substrate pad on the first surface; and
at least one connecting bump on the second surface, and
wherein the first image sensor chip and the second image sensor chip comprise at least one chip pad on at least one upper surface of the first image sensor chip and the second image sensor chip.

12. The image sensor package of claim 11, further comprising:
at least one bonding wire that electrically connects the at least one substrate pad and the at least one chip pad.

13. The image sensor package of claim 12, wherein the first image sensor chip and the second image sensor chip are mounted on the first surface of the package substrate using the at least one bonding wire.

14. The image sensor package of claim 1, further comprising:
an adhesive member between the package substrate and both of the first image sensor chip and the second image sensor chip,
wherein the adhesive member is configured to bond the package substrate to the first image sensor chip and the second image sensor chip.

15. An image sensor package comprising:
a package substrate comprising a first surface and a second surface opposite the first surface;
a first image sensor chip mounted on the first surface of the package substrate;
a second image sensor chip mounted on the first surface of the package substrate and spaced apart from the first image sensor chip in a first direction;
a dust trap between the first image sensor chip and the second image sensor chip;
two fixing members between the first image sensor chip and the second image sensor chip, and spaced apart in a second direction;
a transparent cover spaced apart from upper portions of the first image sensor chip and the second image sensor chip in a third direction; and
a dam interposed between the first image sensor chip and the transparent cover,
wherein the dam is interposed between the second image sensor chip and the transparent cover,
wherein the dam is configured to bond the first image sensor chip and the transparent cover, and bond the second image sensor chip and the transparent cover.

16. The image sensor package of claim 15, wherein a thickness of the dust trap is less than a thickness of the first image sensor chip, and
wherein the thickness of the dust trap is less than a thickness of the second image sensor chip.

17. The image sensor package of claim 15, wherein an uppermost surface of the two fixing members is coplanar with an uppermost surface of the first image sensor chip and the second image sensor chip.

18. The image sensor package of claim 15, further comprising:
a mask pattern in a portion of an upper surface of the transparent cover.

19. The image sensor package of claim 15, further comprising:
a fixing auxiliary member between the two fixing members and extending in the second direction.

20. An image sensor package comprising:
a package substrate comprising a first surface and a second surface opposite the first surface;
a first image sensor chip mounted on the first surface of the package substrate;
a second image sensor chip mounted on the first surface of the package substrate and spaced apart from the first image sensor chip in a first direction;
an adhesive member between the first surface of the package substrate and both of the first image sensor chip and the second image sensor chip, and configured to bond the package substrate to both of the first image sensor chip and the second image sensor chip;
a dust trap between the first image sensor chip and the second image sensor chip;
two fixing members between the first image sensor chip and the second image sensor chip and spaced apart in a second direction;
a transparent cover spaced apart from upper portions of the first image sensor chip and the second image sensor chip in a third direction;
a sealing member on the first surface of the package substrate, surrounding side surfaces of the first image sensor chip and the second image sensor chip, and surrounding side surfaces of the two fixing members; and
a dam interposed between the first image sensor chip and the transparent cover, and between the second image sensor chip and the transparent cover,
wherein the dam is configured to bond the first image sensor chip and the transparent cover, and bond the second image sensor chip and the transparent cover,
wherein a thickness of the dust trap is less than a thickness of the first image sensor chip and a thickness of the second image sensor chip,
wherein an uppermost surface of the two fixing members is coplanar with an uppermost surface of the first image sensor chip and the second image sensor chip, and
wherein the image sensor package further comprises a mask pattern in a portion of an upper surface of the transparent cover.
